(19) United States
(12) Patent Application Publication
(10) Pub. No.: US 2024/0240310 A1
(43) Pub. Date: Jul. 18, 2024

(54) PLASMA RESISTANT COATING, RELATED PRODUCTION METHOD AND USES

(71) Applicant: PICOSUN OY, Espoo (FI)

(72) Inventor: Jesse KALLIOMÄKI, Helsinki (FI)

(21) Appl. No.: 18/562,071

(22) PCT Filed: May 20, 2022
(86) PCT No.: PCT/EP2022/063672

§ 371 Date: Nov. 17, 2023

(30) Foreign Application Priority Data
May 21, 2021 (FI) 20215604

(51) Int. Cl. C23C 16/44; C23C 16/40; C23C 16/455; H01J 37/32

(52) U.S. Cl. CPC C23C 16/4404; C23C 16/403; C23C 16/405; C23C 16/45529; C23C 16/45553; H01J 37/32495

(57) ABSTRACT

A method of producing coated substrates resistant to plasma corrosion and a related coating are provided. The method includes depositing, over at least a portion of a substrate, an yttrium-containing plasma resistant coating through a process of chemical deposition in vapour phase, preferably, through Atomic Layer Deposition (ALD). In some configurations, the plasma resistant coating is formed with a mixture film composed of a mixture of an aluminium oxide compound and an yttrium oxide compound, for example. In some instances, a multilayer laminate structure including the mixture films alternating with deposition films composed of a metal fluoride compound is formed. A coated component for use in a plasma processing apparatus and a method for improving resistance of a substrate to plasma corrosion are further provided.

### FIELD OF THE INVENTION

Present invention generally relates to methods for protecting surfaces in plasma processing methods. In particular, the invention concerns producing plasma resistant coatings on the surfaces of substrates typically exposed to plasma, such as hardware components installed in a processing chamber of a plasma assisted treatment apparatus, for example, by methods of chemical deposition in vapour phase.

### BACKGROUND OF THE INVENTION

Chemical deposition methods in vapour phase, such as Chemical Vapor Deposition (CVD) and Atomic Layer Deposition (ALD), are extensively described in the art. ALD technology, generally regarded as a subclass of CVD processes, has proved an efficient tool for manufacturing high-quality conformal coatings on a variety of three-dimensional substrate structures.

ALD is based on alternating self-saturative surface reactions, wherein different reactants (precursors) provided as molecular compounds or elements in a nonreactive (inert) gaseous carrier are sequentially pulsed into a reaction space accommodating a substrate. Deposition of a reactant is followed by purging the substrate by inert gas. Conventional ALD cycle (a deposition cycle) proceeds in two half-reactions (pulse first precursor—purge; pulse second precursor—purge), whereby a layer of material (a deposition layer) is formed in a self-limiting (self-saturating) manner, typically being 0.05-0.2 nm thick. The cycle is repeated as many times as required for obtaining a film with a predetermined thickness. Typical substrate exposure time for each precursor ranges within 0.1-10 seconds. Common precursors include metal oxides, elemental metals, metal nitrides and metal sulfides.

Vacuum plasma processing chambers are used for plasma processing during fabrication of devices, such as photovoltaics and integrated circuits. Process gases are flowed into the processing chamber while a field is applied to the process gases to generate a plasma of the process gases.

Plasma is an ionised gas, whose very nature means that equipment used in plasma processing methods is susceptible to erosion associated with material evaporation from surfaces, chemical corrosion, changes to the surface structure and morphology, and the like. Plasma erosion and corrosion can drastically reduce the service life of components used in plasma processing equipment. To reduce the operating costs, the lifetimes of the components within a plasma processing chamber exposed to the processing plasma can be extended by designing the components to be plasma resistant.

Yttrium oxide (yttria, Y₂O₃) is known to provide effective protection against oxygen plasma and halogen plasma, such as fluorine and chlorine plasma, for example, generated during plasma-assisted treatments, such as plasma etching or plasma enhanced chemical vapor deposition (PECVD), widely utilized in the integrated circuit (IC) industry.

Typically, yttrium oxide is deposited with physical vapor deposition (PVD) or CVD methods. In comparison to these techniques, ALD methods provide for entirely conformal and coatings with fewer intrinsic defects on a variety of three-dimensional articles. By depositing yttrium oxide on such complex parts as showerheads, gas distribution plates, valves, etc. most prone to plasma corrosion in the equipment for plasma-assisted treatments, mentioned devices and parts thereof can be rendered with additional resistance to corrosion, in particular, plasma corrosion, thus prolonging life-time of the equipment and markedly reducing costs associated with corrosion induced repair- and maintenance.

One of the main complications arising in deposition of yttrium oxide films by ALD is associated with difficulties in achieving uniform coatings using yttrium precursors together with water in large-scale reaction/deposition chambers. Pure yttrium oxide film is of hygroscopic nature and it tends to absorb water molecules, which unavoidably leads to the following problems: drifting GPC (Growth per Cycle) rates (the process becomes difficult to control, which causes problems particularly in applications which require thick films), and high local variations in H₂O, since water as precursor is absorbed more upstream (therefore making it troublesome to scale the process up to large chambers). Moreover, water absorption and desorption rates depend on a substrate geometry, which is inconvenient for coating of complex 3D parts. The issue becomes more pronounced as the film volume increases, making it particularly problematic when thick films preferred by this application are desired.

On the other hand, a process using ozone (O₃) as an oxidizer has produced a stable carbonate intermediate which requires high temperature (T>325° C.) to decompose, which turned out extremely high temperature for the most of commercial realizations.

A number of ALD enabled materials, such as aluminum oxide (alumina, Al₂O₃), for example, are known to produce fully conformal coatings also in conditions of high-speed deposition. However, several attempts to use pure alumina coatings against plasma corrosion have revealed that its' (plasma) etch resistance was poor (about 10 times worse than pure Y₂O₃).

Moreover, deposition of pure yttrium oxide through ALD was associated with lack of uniformity and formation of side products. Another encountered problem is that yttrium precursors tend to have very low vapor pressure and are susceptible to recondensation. These precursors are also extremely malodorous even in low concentrations.

Mitigating all these issues extends deposition cycles, and hence significantly reduces time- and cost-effectiveness of the entire process. Furthermore, in the event the chemical deposition equipment is constructed without heated pump lines, reaction by-products tend to condense in the exhaust line and when the reaction chamber is opened, said by-products are released to the ambient causing health hazards to the equipment operators.

In this regard, an update in the field of producing plasma-resistant coatings through the methods of chemical deposition in vapour phase, such as ALD, is still desired, in a view to address the challenges associated with selection of reactive compounds suitable for generating long-lasting protection coating against different types of plasma in a robust and cost-effective manner.

### SUMMARY OF THE INVENTION

An objective of the present invention is to solve or to at least alleviate each of the problems arising from the limitations and disadvantages of the related art. The objective is achieved by various embodiments of a method for producing plasma resistant coated substrates, related plasma resistant coating and uses.

In an aspect, a method for producing plasma resistant coated substrates is provided, according to what is defined in independent claim 1.

In an embodiment, the method for producing plasma resistant coated substrates comprises: obtaining a substrate, and depositing, over at least a portion of the substrate, an yttrium-containing plasma resistant coating through a process of chemical deposition in vapour phase, preferably, through Atomic Layer Deposition (ALD), wherein said plasma resistant coating comprises a mixture film composed of a mixture of at least two compounds, one of said compounds being an yttrium compound, in particular, yttrium oxide.

In an embodiment, the mixture film is deposited in a plurality of deposition sequences, each said deposition sequence comprises depositing a first compound in at least two deposition cycles followed with depositing a second compound in a single deposition cycle, the second compound being the yttrium compound.

In an embodiment, the relationship between the number of deposition cycles to deposit the first compound and the number of deposition cycles to deposit the second compound in the deposition sequence is 2-10 to 1, respectively.

In an embodiment, the mixture film is composed of a mixture of said first compound and said second compound, in which mixture the second compound is yttrium(III) oxide (Y₂O₃) and the first compound is a metal oxide distinct from yttrium oxide, such as any one of aluminium(III) oxide (Al₂O₃) and zirconium(IV) oxide (ZrO₂), or any non-lanthanide oxide.

In an embodiment, the mixture film is composed of a mixture of aluminium(III) oxide (Al₂O₃) and yttrium(III) oxide (Y₂O₃) to yield a solid solution of aluminium yttrium oxide (AlₓY₂₋ₓO₃, where x is >1).

In another embodiment, the method further comprises: depositing, over a deposition layer consisting of the mixture film, an additional deposition layer composed of a metal fluoride.

In an embodiment, in said method the steps of depositing the mixture film and of the additional deposition layer compound of the metal fluoride are repeated a number (n) of times to produce a laminate coating of a desired thickness.

In an embodiment, a metal component in the metal fluoride, said additional deposition layer is composed of, is selected from the group consisting of: yttrium (Y), lanthanum (La), strontium (Sr), zirconium (Zr), magnesium (Mg), hafnium (Hf), terbium (Tb), and calcium (Ca). Preferred metal elements include lanthanum and yttrium, with yttrium being the most preferred.

In an aspect, a plasma resistant coating is provided, according to what is defined in independent claim 9.

In an embodiment, the coating comprises a mixture film composed of a mixture of at least two compounds, one of said compounds being an yttrium compound, preferably, yttrium oxide.

In an embodiment, the coating comprises the mixture film being deposited in a plurality of deposition sequences, each said deposition sequence comprises depositing a first compound in at least two deposition cycles, in particular, in 2-10 deposition cycles, followed with depositing a second compound in a single deposition cycle, the second compound being the yttrium compound.

In an embodiment, the coating comprises the mixture film composed of a mixture of said first compound and said second compound, in which mixture the second compound is yttrium(III) oxide (Y₂O₃) and the first compound is a metal oxide distinct from yttrium oxide, such as any one of aluminium(III) oxide (Al₂O₃) and zirconium(IV) oxide (ZrO₂).

In an embodiment, the coating comprises the mixture film composed of a mixture of aluminium(III) oxide (Al₂O₃) and yttrium(III) oxide (Y₂O₃) to yield a solid solution of aluminium yttrium oxide (AlₓY₂₋ₓO₃), where x is >1.

In an embodiment, the coating comprises the mixture film, in which the content of yttrium is within a range of about 4 atomic percent to about 20 atomic percent.

In an embodiment, the coating further comprises at least one additional deposition layer composed of a metal fluoride.

In an embodiment, the coating is configured as a multilayer laminate coating, in which a plurality of layers composed of yttrium-containing mixture films alternate with a plurality of deposition layers composed of the metal fluoride.

In an embodiment, a metal component in the metal fluoride, said additional deposition layer is composed of, is selected from the group consisting of: yttrium (Y), lanthanum (La), strontium (Sr), zirconium (Zr), magnesium (Mg), hafnium (Hf), terbium (Tb), and calcium (Ca). In an embodiment, said additional deposition layer of the plasma resistant coating is composed of metal fluoride, such as is yttrium(III) fluoride (YF₃).

In an embodiment, the coating has thickness within a range of about 10 nm to about 1000 nm, preferably, within a range of about 50 nm to about 300 nm.

In another aspect, a coated item is provided, according to what is defined in independent claim 18. The coated item comprises a substrate coated with a plasma-resistant coating according to the embodiments.

In some instances, the substrate may be any one metal, metal alloy, quartz, semiconductor and/or ceramics.

In an embodiment, the coated item is configured as a component used with a plasma processing equipment and having a surface or surfaces exposed to plasma. Said component can be configured as an article selected from the group consisting of: a showerhead, a diffusor for the showerhead, a pedestal, a sample holder, a valve, a valve block, a pin, a manifold, a pipe, a cylinder, a lid, and a container.

In a further aspect, use of the coated item and/or of the substrate coated with the plasma resistant coating, according to the embodiments, in a processing chamber of a plasma assisted treatment apparatus is provided, according to what is defined in independent claim 21.

In still a further aspect, a method for improving resistance of a substrate to plasma erosion and corrosion in plasma processing is provided according to what is defined in independent claim 22.

The utility of the present invention arises from a variety of reasons depending on each particular embodiment thereof. Overall, the invention offers a method for producing coatings resistant to merely all types of plasma corrosion using existing well-established techniques for ALD-depositing the alumina layers.

Plasma etch tests with Al₂O₃—Y₂O₃ and ZrO₂—Y₂O₃ mixture film coatings according to some embodiments have demonstrated that the mixture film coating having a content of yttrium of about 4-20 atomic percent (at. %) yields similar resistance against halogen and oxygen plasma as pure Y₂O₃. However, the mixed oxide coating does not encounter the water absorption issue discussed herein above, which can be explained by the fact that formation of polycrystalline Y₂O₃ phase is interrupted by another dissimilar oxide compound. That is, Al₂O₃ (or ZrO₂, or any non-lanthanide oxide) will prevent the yttria phase from forming thus solving the problem of hygroscopic bulk.

The proposed method allows for producing uniform, homogenous coating in much shorter time periods (the tests have demonstrated that overall deposition time decreased about 17 times), in comparison to the processes required for deposition of pure yttrium oxide films, which is explained with shortened purge periods (typical Y₂O₃ depositions require long purges after water with inert fluid). At the same time, the coating films deposited according to the disclosed methods, possess plasma barrier properties similar to that of pure yttrium oxide.

On the other hand, the proposed method exploits same precursor chemicals and essentially the same conditions as those developed for deposition of alumina films. However, due to a mixed nature of the solid films produced herewith and the presence of an yttria component therein, the coatings deposited by the proposed methods can be made about 85% thinner in comparison to conventional alumina films, but still preserve the same resistance properties against plasma. Taken the shortened deposition time, the process allows for coating a greater number of samples in the same time-period, thus reducing the process associated costs while maintaining production related quality.

Deposition layers deposited by ALD methods have fewer intrinsic defects and fully conformal, which renders the proposed technology highly suitable for coating profiled articles of complex 3D shapes. The methods proposed herewith provide for manufacturing corrosion resistant items from profiled substrates, such as showerheads and diffusors for showerhead, with protective coating layers against halogen-, oxygen- and argon plasmas, for example.

The method further allows for extending operational lifetime (time the components are in operation before maintenance) for the components typically exposed to plasma.

In the present disclosure, materials with a layer thickness below 1 micrometer (μm) are referred to as “thin films”.

The expressions “reactive fluid” and/or “precursor fluids” are indicative in the present disclosure of a fluidic flow comprising at least one chemical compound (a precursor compound), hereafter, a precursor, in an inert carrier.

The expression “a number of” refers herein to any positive integer starting from one (1), e.g. to one, two, or three; whereas the expression “a plurality of” refers herein to any positive integer starting from two (2), e.g. to two, three, or four.

The terms “first” and “second” are not intended to denote any order, quantity, or importance, but rather are used to merely distinguish one element from another, unless explicitly stated otherwise.

### BRIEF DESCRIPTION OF THE DRAWINGS

FIG. 1 schematically illustrates a substrate 20 with a coating 10 produced according to an embodiment.

FIGS. 2A and 2B schematically illustrates a substrate 20 with a coating 10A produced according to another embodiment; where FIG. 2A schematically illustrates formation of a deposition stack for the coating 10A.

FIGS. 3A and 3B illustrate experimental results (film composition) for the coating 10, according to the embodiment.

### DETAILED DESCRIPTION OF THE EMBODIMENTS

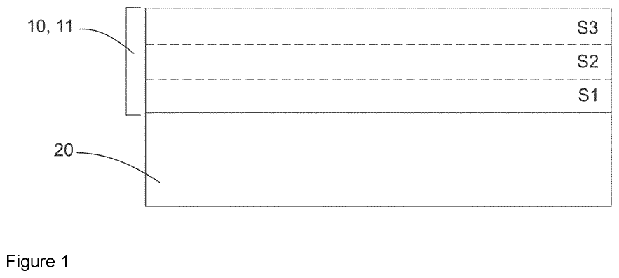

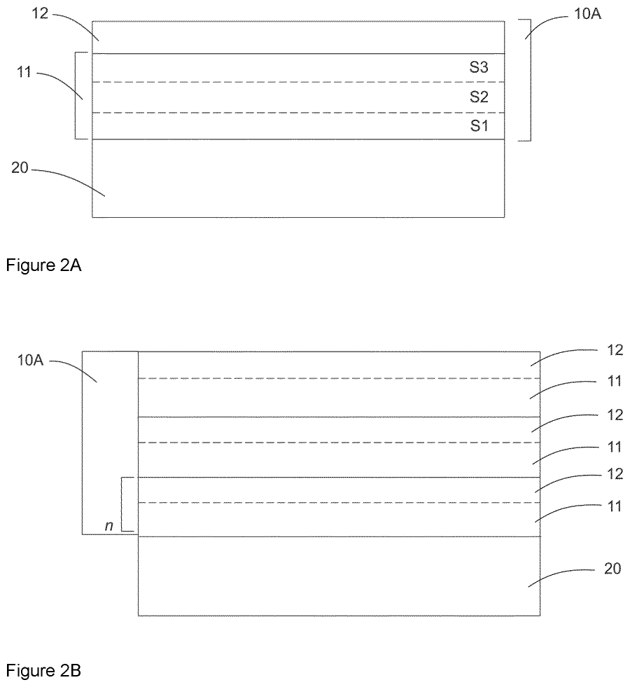

FIGS. 1, 2A and 2B illustrate, at 10 and 10A, respectively, a plasma resistant coating, hereafter, a coating, produced in accordance with the embodiments.

The term “plasma resistant” refers herein to a resistance to erosion and/or corrosion generally regarded as degradation of substrate material being in frequent contact with plasma, such as when exposed to the plasma processing conditions generated in a processing chamber of a plasma processing apparatus.

The coating 10, 10A is advantageously designed for substrates exposed, at least partly, to plasma corrosion in conditions of plasma processing. Such substrates include conventional hardware components used in equipment for plasma processing, such as plasma etchers, reactors for plasma-enhanced chemical vapor deposition (PECVD) or for plasma-assisted physical vapor deposition (PVD).

Typical hardware components include, but are not limited to showerheads, diffusors for showerheads, pedestals, sample holders, valves, valve blocks, pins, manifolds, pipes, cylinders, lids, and various containers.

To prevent degradation of material caused with plasma, it is proposed to protect the substrates 20 with the newly developed coating 10, 10A (FIGS. 1, 2B). The coating comprises- or consists of a mixture film 11 composed of a mixture of at least two compounds, one of said compounds being yttrium compound, in particular, yttrium oxide. In a number of configurations, another compound forming the mixture film is a metal oxide compound distinct from yttrium oxide.

In some instances, the coating is implemented as a multilayer laminate structure (10A), in which deposition layers composed of the mixture film alternate with deposition layers composed of a metal halide, preferably, a metal fluoride. In said laminate structure, the yttrium-containing mixture films alternate with films formed with a pure metal fluoride. The term “pure” is used hereby in a meaning that a compound, hereby, the metal fluoride, does not form a part of the mixture. In some instances, the laminate structure 10A comprises the mixture film covered with a topmost deposition layer composed of metal halide, preferably, metal fluoride.

Deposition layers are formed on the substrate through a process of chemical deposition in vapour phase, preferably, through Atomic Layer Deposition (ALD).

The basics of an ALD growth mechanism are known to a skilled person. ALD is a chemical deposition method based on temporally separated introduction of at least two reactive precursor species to at least one substrate placed in a reaction vessel to deposit material on substrate surfaces by sequential self-saturating surface reactions. It is to be understood, however, that one of these reactive precursors can be substituted by energy when using, for example, photon-enhanced ALD or plasma-enhanced ALD, for example PEALD, leading to single precursor ALD processes. For example, deposition of a pure element, such as metal, requires only one precursor. Binary compounds, such as oxides can be created with one precursor chemical when the precursor chemical contains both of the elements of the binary material to be deposited. Thin films grown by ALD are dense with fewer intrinsic defects and have uniform thickness.

In terms of overall implementation, a deposition setup may be the one based on an ALD installation trademarked as the PICOSUN® P-300B ALD system or the PICOSUN® P-1000 ALD system available from Picosun Oy, Finland. Nevertheless, the features underlying a concept of the present invention can be incorporated into any other chemical deposition reactor embodied as an ALD, MLD or CVD device, for example, or any subtype thereof, such as photon-enhanced Atomic Layer Deposition (known also as photo-ALD or flash enhanced ALD), for example.

An exemplary ALD reactor comprises a reaction chamber that establishes the reaction space (deposition space), in which the production of nanolaminate coatings described herewith takes place. The reactor further comprises a number of appliances configured to mediate fluidic flow (inert fluids and reactive fluids containing precursor compounds P1, P2) into the reaction chamber. These appliances are provided as a number of intake lines/feedline and associated switching and/or regulating devices, such as valves, for example.

A basic ALD deposition cycle consists of four sequential steps: pulse A, purge A, pulse B and purge B. Reactive fluid entering the reaction chamber during pulses A and B is preferably a gaseous substance comprising a predetermined precursor chemical (P1, P2) carried by an inert carrier (gas). Delivery of the precursor chemicals into the reaction space and film growth on the substrate is/are regulated by means of the above said regulating appliances, such as e.g. three-way ALD valves, mass-flow controllers or any other device suitable for this purpose.

The above described deposition cycle can be repeated until the deposition sequence has produced a thin film or coating of desired thickness. Deposition cycles can also be either simpler or more complex. For example, the cycles can include three or more reactant vapor pulses separated by purging steps, or certain purge steps can be omitted. On the other hand, photo-enhanced ALD has a variety of options, such as only one active precursor, with various options for purging. All these deposition cycles form a timed deposition sequence that is controlled by a logic unit or a microprocessor.

In the method of the present invention, the plasma resistant coating films 10, 10A can be uniformly applied on any kind of substrate 20, including non-specific macroscopic and/or profiled 3D objects, at the deposition temperature of within a range of 150-350° C., specifically, at about 300° C., in large-scale ALD reaction chambers. An example of the large-scale ALD tool is the P-1000 ALD batch system from Picosun®, which has a reaction chamber with the maximum cross section 470 mm×470 mm (as square) with the maximum diameter of 600 mm (as circular) and the maximum height of 700 mm.

The method discussed in the present disclosure thus allows for depositing uniform yttrium-containing, plasma resistant coatings on the substrates in large ALD chambers.

With reference to FIG. 1, illustrative of the coating 10 consisting of the mixture film 11, the mixture film 11 is deposited in a plurality of deposition sequences (S1, S2, S3 . . . Sₙ), such as ALD deposition sequences, wherein each said deposition sequence comprises depositing a first compound in at least two deposition cycles followed with depositing a second compound in a single deposition cycle. In deposition sequences aiming at producing the mixture film, the second compound is an yttrium compound.

In some configurations, the mixture film 11 is thus composed of a mixture of the first compound and the second compound, in which mixture the second compound is yttrium(III) oxide (Y₂O₃) and the first compound is a metal oxide distinct from yttrium oxide, such as any one of aluminium(III) oxide (Al₂O₃) and zirconium(IV) oxide (ZrO₂).

In some other configurations said first compound is provided as strontium oxide (SrO), niobium(IV) oxide (NbO₂), hafnium(IV) oxide (HfO₂), or tantalum(V) oxide (Ta₂O₅). Utilization of any other appropriate compound, such as a non-lanthanide oxide, for example, is not excluded.

In a configuration, the mixture film 11 forming the coating 10 is composed of a mixture of aluminium(III) oxide (Al₂O₃) and yttrium(III) oxide (Y₂O₃) to yield a solid solution of aluminium yttrium oxide (AlₓY₂₋ₓO₃, where x>1).

The expression “solid solution” is utilized is the present disclosure interchangeably with the expression “mixture film”. It is used to indicate a mixed layer of (nano)material, which exists in homogeneous solid phase having a second component completely and evenly dispersed in a solid medium. According to some literature sources, one of the components in solid solutions acts as a “host” (corresponding to a solvent in a liquid solution) and the other component(s) take(s) a role of a “guest” (corresponding to dissolved substance(s) in a liquid solution). Experimental data (e.g. x-ray spectra) for the solid solutions of that kind are typically expected to match the data for the pure “host” component.

In present example, the “host” component is a first compound, herein, non-yttrium metal oxide (e.g. Al₂O₃), while yttrium oxide (Y₂O₃) acts as a “guest” (a second compound). To generate an exemplary solid solution/the mixture film 11, during the deposition process, the following deposition sequence is adopted. At first, Al₂O₃ is deposited in a number of deposition cycles from trimethylaluminum (TMA, Al(CH₃)₃) used as a 1^{st} precursor and water used as 2^{nd} precursor.

Same deposition sequence continues with depositing yttrium oxide from yttrium precursor (1^{st} precursor) and water (2^{nd} precursor), for example, in one deposition cycle. This creates a sub-monolayer of “Y₂O₃” (taken in parentheses because no distinguishable Y₂O₃ layer(s) or even particles are present in the “host” substance).

The deposition process continues with the next deposition sequence, wherein deposition of Al₂O₃ is followed with deposition of Y₂O₃. In this way, the “Y₂O₃” is completely and evenly dispersed in the solid medium (Al₂O₃ or other suitable “host” compound) to yield a solid solution of aluminium yttrium oxide (ALY₂-ₓO₃). In the present disclosure, said solid solution of aluminium yttrium oxide is also denoted as Al₂O₃—Y₂O₃.

Use of other appropriate precursors is not excluded. For example, whether zirconia (ZrO₂) is used as the first compound, it may be deposited using tetrakis(ethylmethyl-amino)zirconium (TEMAZr) and H₂O precursors.

Thin ALD coatings are generally amorphous (not crystalline), therefore, the mixture film 11 formed hereby should be rather described as a “solution”; on the contrary to doped semiconductors or ordered, crystalline materials.

To avoid confusion, we note that the boundaries between the “layers” produced by each deposition sequence (S1, S2, S3 . . . Sₙ) indicated on FIGS. 1 and 2 with dashed lines are intended to serve merely illustrative purposes. In practice, the mixture film layer 11 is deposited as a uniform, homogenous material layer, as described above.

The relationship between the number of deposition cycles to deposit the first compound (e.g. Al₂O₃) and the number of deposition cycles to deposit the second compound (e.g. Y₂O₃) in the deposition sequence is 2-10 to 1, respectively. In some instances, the first compound can be deposited in 2-7 cycles (per a deposition sequence: S1, S2, S3 . . . Sₙ). However, the second (“guest”) compound is deposited in one cycle per deposition sequence.

Hence, the content of yttrium in the mixture film 11 is within a range of about 4 atomic percent (at. %) to about 20 atomic at. %. In some instances, the total yttrium content in the mixture film 11 is typically within a range of about 5-20 at. %.

An exemplary process to produce the coating 10 provided as a mixture film 11 is presented in Example 1. The mixture film 11 thus formed is a solid solution of aluminium yttrium oxide (AlₓY₂₋ₓO₃).

### Example 1. Formation of the Coating 10 Provided as a Mixture Film AlₓY₂₋ₓO₃ (Solid Solution)

1. Formation of a first compound (Al₂O₃):
   1a. Pulse 1^{st} precursor (e.g. TMA) to form the first compound;
   1b. Pulse 2^{nd} precursor (H₂O or O₃) to form the first compound.
Repeat 1a and 1b 1-9 times (to achieve a total number of deposition cycles of 2-10).
2. Formation of a second compound (Y₂O₃):
   2a. Pulse 1^{st} precursor to form the second compound (any suitable Y-precursor, e.g. Tris(methylcyclopenta-dienyl)yttrium(III)/Y(MeCp)₃);
   2b. Pulse 2^{nd} precursor (e.g. H₂O) to form the second compound.

The end of a first deposition sequence.

Repeat the deposition sequence (steps 1 (1a-1b) and 2 (2a-2b)) a predetermined number of times to generate a mixture film 11 (aka the coating 10) of a desired thickness. By way of example, in order to deposit the coating having depth/thickness within a range of about 180 nm to about 9,900 nm, the steps 1 and 2 can be repeated 1000-10,000 times.

In some particular example, a deposition sequence to produce the mixture film 11 includes three (3) deposition cycles of TMA-H₂O (to produce the first compound, herein, Al₂O₃) and one cycle of Y(MeCp)₃-H₂O (to produce the second compound, herein Y₂O₃). In present example the total yttrium content in the mixture film 11 is within a range of about 10 at. %.

Overall, we emphasize that the yttrium compound is deposited in one cycle (aka one cycle of Y-precursor and H₂O, for example) per a deposition sequence.

Suitable Y-precursors include, but are not limited to: Y(thd)₃ (yttrium(III) tris(2,2,6,6-tetramethyl-3,5-heptanedionate)); Y(Cp)₃ (tris(cyclopentadienyl) yttrium(III)); Y(EtCp)₃ (tris(ethylcyclopentadienyl)yttrium(III)); Y(iPrCp)₃ (tris(i-propylcyclopentadienyl)yttrium(III)); Y(n-BuCp)₃ (tris(n-butylcyclo-pentadienyl)yttrium(III)); Y(s-BuCp)₃ (tris(s-butylcyclopentadienyl)yttrium(III)); Y(EDMDD)₃ (tris(6-ethyl-2,2-dimethyl-3,5-decanedionato)yttrium); ARYA™ YERBA™ (the latter two available from Air Liquide).

The coating 10 deposited as described above typically has a thickness within a range of about 10 nm to about 1000 nm, preferably, within a range of about 50 nm to about 300 nm. In some particular examples, the coating 10 can be formed with the thickness of about 20-100 nm.

Still, the ALD technology utilized hereby allows deposition of the coatings 10 with the thickness exceeding 1000 nm, e.g. up to 2 or 3 micrometers (μm), or even up to 10 micrometers.

The plasma resistant coating 10 composed of the mixture film 11 has been deposited using the ALD systems P-300B and P-1000, both Picosun©. Follow-up tests have demonstrated that the coating 10 (P-300B) has preserved the plasma corrosion resistant properties the most, as compared to conventional coatings composed of (pure) Y₂O₃. Thus, the mixture film 11 (and the coating 10 formed of said film) containing about 20 at. % of yttrium possesses similar corrosion resistance (about 80% in absolute terms and about 85% when compared to alumina films) against plasma, such as fluorine or oxygen plasma, for example, as conventional Y₂O₃ films and significantly higher corrosion resistance as compared to alumina (Al₂O₃) films of similar thickness.

Keeping the overall content of yttrium in the mixture film 11 within a range of about 4-20 atomic percent allows for producing the coating 10 according to existing and robust ALD processes (i.e. in the same manner as an alumina film would be deposited from TMA-H₂O, for example).

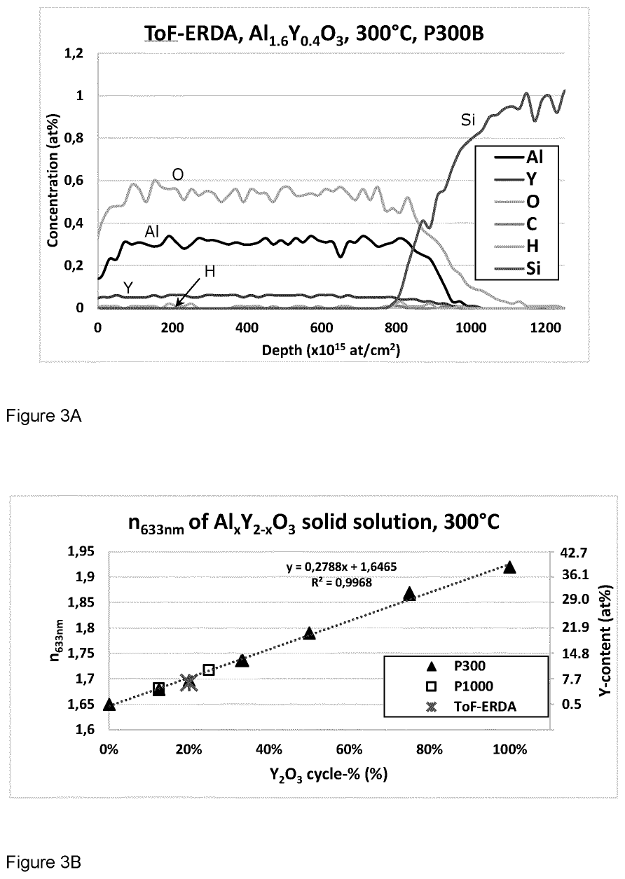

FIGS. 3A and 3B illustrate experimental results related to composition of the coating 10 (deposited on P-300B at 300° C.). Observed film composition matched expectations and was consistent throughout the film (see Table 1 below and FIG. 3A showing the results of Time-of-Flight Elastic Recoil Detection Analysis (ToF ERDA) analysis). Impurity levels were very low.

TABLE 1
Composition of the coating 10 formed of the mixture film 11.

| | Al | Y | O | C | H |
|---|---|---|---|---|---|
| Concentration (at %) | 33.9 | 6.12 | 59.4 | 0.6 | <DL |
| Uncertainty | 0.4 | 0.07 | 0.5 | 0.07 | 0.02 |

According to X-ray reflectometry (XRR) measurements, the coating 10 had density of 3.45±0.05 g/cm³ and roughness of 0.74±0.01 nm.

Film composition can be estimated accurately from the refractive index (n) measured at 633 nm wavelength of the solid solution coating 10 (FIG. 3B). Composition is not a deposition tool dependent. The results are summarized in Table 2 below (see also FIG. 3B).

TABLE 2
The results obtained from measing refractive index (n) at 633 nm of the
coating 10 formed of the mixture film 11 (solid solution AlₓY₂₋ₓO₃).

| | Al | Y | O | C | H | Formula |
|---|---|---|---|---|---|---|
| ToF-ERDA | 33.9 | 6.12 | 59.4 | 0.6 | <DL | Al_{1.7}Y_{0.3}O₃ |
| Experimental* | 33.3 | 6.67 | 60.0 | 0 | 0 | Al_{1.67}Y_{0.33}O₃ |
| Calculated** | 32.0 | 8.0 | 60.0 | 0 | 0 | Al_{1.6}Y_{0.4}O₃ |

*Refers to an expected value based on an experimental model.
**Refers to a real measurement data obtained in ToF-ERDA measurements.

With reference to Table 2 and FIG. 3B, the experimental model is the linear fit, where the n-values are plotted against Y₂O₃ cycle ratio. The slope and the intersection allow one to estimate the yttrium content of the solid solution (the mixture film 11) forming the coating 10, which was later confirmed by ToF-ERDA measurements.

Coating uniformities on flat surfaces and on profiled 3D objects were tested for the coatings 10 deposited using the large-scale ALD system P-1000. It has been found out that the process upscales well and uniform coatings with fewer intrinsic defects can be deposited on large substrates in reaction chambers dimensioned as the ALD tool P-1000. In the test trials, deposition temperature was 300° C.; duration of non-yttrium pulses was 0.5 s, and duration of purges was 30-40 s.

Overall, it has been demonstrated that the mixture film 11 (solid solution AlₓY₂₋ₓO₃) can be formed through a well-established process using TMA and water precursors (only one cycle for deposition of the yttrium compound is needed per a deposition sequence). One of the key finding was that the corrosion resistance possessed by the mixture film does not correlate linearly with its Y₂O₃ content. Thus, if the etch rate of pure Y₂O₃ is 1, the etch rate of the coating 10 formed with the mixture film 11 ranges from 1.5 to 2 times that rate, while the pure Al₂O₃ demonstrates 10×the etch rate of (pure) Y₂O₃. Still, in comparison to the coatings made of pure yttria, the mixture film coating 10 is more uniform and its deposition is much faster.

At the same time, plasma resistance of the coating 10 was about five (5) times higher than that of conventional alumina films. The coating 10 possessing above mentioned barrier properties was deposited in a number of deposition sequences, wherein each deposition sequence included three deposition cycles of TMA-H₂O (to produce Al₂O₃) and one cycle of Y-precursor-H₂O (to produce Y₂O₃). A significantly thinner coating (10) can thus be used to provide the same anticorrosive properties as compared to conventional alumina coatings.

In other words, the mixture film coating 10 possesses similar resistance to plasma, in particular, fluorine plasma, as the coatings composed of pure yttria (and about times better resistance as compared to pure alumina coatings). At the same time, the mixture film coating (10) can be deposited with well-established techniques, such as the ones used for the deposition of Al₂O₃.

Reference is made to FIGS. 2A and 2B illustrating formation of the plasma resistant coating according to another embodiment. To deposit the coating 10A (FIGS. 2A, 2B), the method generally discussed above and presented in Example 1 is further extended in a manner that over a deposition layer consisting of the yttrium-containing mixture film 11, an additional deposition layer 12 is deposited. The additional deposition layer 12 is preferably composed of a metal fluoride.

A metal component in the metal fluoride is represented with at least the following chemical elements: yttrium (Y), lanthanum (La), strontium (Sr), zirconium (Zr), magnesium (Mg), hafnium (Hf), terbium (Tb), and calcium (Ca).

Metal fluoride compounds include, but not limited to yttrium(III) fluoride (YF₃), lanthanum(III) fluoride (LaF₃), strontium(II) fluoride (SrF₂), zirconium(IV) fluoride (ZrF₄), magnesium(II) fluoride (MgF₂), hafnium(IV)fluoride (HfF₄), terbium(III) fluoride (TbF₃), and calcium(II) fluoride (CaF₂). Any other appropriate compound can be utilized. Preferred compounds include LaF₃ and YF₃, with YF₃ being the most preferred. Hence, in some specific configuration, the additional deposition layer 12 is composed of yttrium(III) fluoride (YF₃).

The metal fluoride forming said additional deposition layer is further referred to as “pure” in a meaning that said compound does not form a part of the mixture.

In some other instances, the additional deposition layer may be composed of a metal halide compound, different to metal fluoride, such as a metal chloride (e.g. yttrium chloride), for example.

FIG. 2A illustrates formation of the additional deposition layer 12 atop the mixture film 11. Said additional deposition layer 12 can be deposited over the mixture film 11 described herein above (rf. Example 1) as a single topmost layer.

Deposition process may still continue in a manner that the steps of depositing the mixture film 11 and of the additional deposition layer 12 composed of the metal fluoride (shown on FIG. 2A) are repeated a number (n) of times to produce a laminate coating of a desired thickness. FIG. 2B illustrates the laminate coating 10A comprising the alternating layers 11 and 12.

The coating 10A may thus comprise a plurality of deposition layers (cf. layers 11, 12 repeated n times) arranged atop each other to form a “stack”. The layers 11, 12 form a “sub-stack” (in a manner shown on FIG. 2A). For the sake of clarity, we note that a total number of said sub-stacks (n) and the total number of deposition layers, respectively, may vary dependent on layer composition, a substrate to be coated and an application field of the latter. By way of example, total number of “sub-stacks” may vary within a range of 2-100. In most instances, n varies within a range of 5-20.

An exemplary process to produce the laminate coating 10A comprising a number of “sub-stacks” 11, 12 repeated n times is presented in Example 2. In the example, the deposition layer 11 is the mixture film (solid solution) of aluminium yttrium oxide (AlₓY₂₋ₓO₃) and the deposition layer 12 is the metal fluoride.

### Example 2. Formation of the Laminate Coating 10A

I. Formation of the deposition layer 11.
1. Formation of a first compound (Al₂O₃):
   1a. Pulse 1^{st} precursor (e.g. TMA) to form the first compound;
   1b. Pulse 2^{nd} precursor (H₂O or O₃) to form the first compound.

Repeat 1a and 1b 1-9 times (to achieve total number of deposition cycles of 2-10).
2. Formation of a second compound (Y₂O₃):
   2a. Pulse 1^{st} precursor to form the second compound (any suitable Y-precursor, e.g. Tris(methylcyclopenta-dienyl)yttrium(III)/Y(MeCp)₃);
   2b. Pulse 2^{nd} precursor (e.g. H₂O) to form the second compound.

The end of a first deposition sequence.

Repeat the deposition sequence (steps 1 (1a-1b) and 2 (2a-2b)) a predetermined number of times to generate a mixture film 11 of a desired thickness. By way of example, in order to deposit the coating having depth/thickness of 20-100 nm the steps 1 and 2 can be repeated 200-500 times.
II. Formation of the deposition layer 12.
3. Formation of an additional deposition layer composed of the metal fluoride (herein, yttrium fluoride, YF₃):
3a. Pulse 1^{st} precursor to form the deposition layer 12 (any suitable Y-precursor, e.g. Y(hfac)₃EME);
3b. Pulse 2^{nd} precursor to form the deposition layer 12 (e.g. O₃).
Repeat 3a and 3b 100-600 times.

Steps I and II may be repeated a predetermined number (n) of times to reach a target thickness of the laminate coating 10A comprising alternating layers 11 and 12.

Deposition process of Example 2 can be conducted by repeating step I a predetermined number of times to produce the mixture film 11 of a desired thickness, followed with formation of a topmost deposition layer 12 according to step II. The laminate structure 10A is thus created containing the mixture film 11 and the additional deposition layer 12 composed of metal fluoride.

When the metal fluoride used is yttrium fluoride, then deposition of yttrium fluoride can be accomplished with different precursors, e.g. with a combination of Y(thd)₃-TiF4 (P1-P2), or any other appropriate compounds including Y-precursors indicated in conjunction with depositing the mixture films 11 (and the coating 10).

For the laminate coating 10A it may be preferred that the process stages I and II (steps 2a and 3a, respectively) utilize different yttrium precursors (Y(MeCp)₃ and Y(hfac)₃EME, respectively). However, utilization of the same Y-precursor throughout the entire process is not excluded.

In the coating 10A, a stack formed with a plurality of deposition layers has a thickness within a range of about 10 nm to about 1000 nm; therefore, the laminate structure presented herewith is also referred to as “nanolaminate”. With regard to the coating 10A, the expressions “a structure” (nanolaminate structure) and “a stack” (nanolaminate stack) are used in the present disclosure interchangeably. Nanolaminate stacks having thicknesses within a range of 10 nm to 1000 nm, preferably, within a range of 50 nm to 500 nm, still preferably, within a range of 100 to 300 nm, can be produced. Most typical and, in some instances, preferred ranges for the deposited nanolaminate structures 10A include 50-300 nm, namely, 50 nm, 100 nm, 150 nm, 200 nm, 250 nm, and 300 nm.

In the laminate structure 10A, the deposition layers 11 composed of the mixture film (forming the coating 10) typically have the thickness of 20-100 nm.

Still, the ALD technology utilized hereby allows production of laminate structures 10A having thicknesses exceeding 1000 nm (up to about 2-3 micrometers or even up to 10 micrometers) by repeating the steps I and II (Example 2) a predetermined number (n) of times.

In practice, by repeating the steps I and II (Example 2) 5-20 times, the laminate coating having the thickness within a range of 250 nm to up to 10,000 nm can be produced.

With reference to FIG. 2B, the individual deposition layers (11)ₙ, (12)ₙ are formed in a number of deposition cycles (with a basic sequence of P1—purge—P2—purge as per any of the examples above).

The process to produce any one of the coatings 10, 10A may further include the steps of preprocessing and postprocessing. Thus, the process may further include: obtaining a substrate 20 and placing the substrate into the reaction/processing chamber of a related chemical deposition apparatus, such as a processing chamber of the ALD apparatus. The chamber and the substrate are further heated to 150-325° C. to let the chamber stabilize. Optionally, the substrate is preprocessed to prepare its surface for further deposition: the substrate can be treated in situ with a suitable gas and/or an additional ALD layer can be deposited thereon to improve adhesion of the coating 10, 10A, for example. After the coating 10, 10A is deposited, the substrate is preferably allowed to cool in vacuum, in inert atmosphere or in ambient air.

Nevertheless, it has been demonstrated that deposition of the coating 10 provided as a solid solution film 10 on a substrate, which is not silicon (e.g. metal), does not require pretreatment of said substrate for the coating 10 to adhere. A number of experimental trials has been carried out involving the coating 10 provided as a solid mixture film of Al₂O₃—Y₂O₃ on silicon (Si) and metal (stainless steel) substrates. Total thickness of the coating 10 was 300 nm. Resistance of the coating to separation from substrates was assessed in accordance with the standard ISO 2409:2013 (Paints and varnishes Cross-cut test). Tested samples included: 1) Si substrate coated with 10, no pretreatment; 2) SS substrate coated with 10, no pretreatment; 3) SS substrate pretreated with O₃ (30 min) and coated with 10; 4) SS substrate coated with 10 and subjected to wash procedure*; 5) SS substrate pretreated with O₃ (30 min), coated with 10 and subjected to wash procedure*.

*Wash procedure included the following steps: 1) Isopropyl alcohol (IPA) in ultrasonic, 5 min, RT; 2) Deionized water in ultrasonic, 5 min, RT; 3) Repeat steps 1 and 2; 4) Dry with nitrogen gas (N₂).

In all tested samples (1-5), the coating 10 demonstrated adequate adhesion (Class 0) to substrates, including stainless steel substrates absent any pretreatment.

Both coatings 10, 10A offer outstanding anti-corrosion properties. For example, the coating 10 provided as a solid mixture (Al₂O₃—Y₂O₃) film has the most of the Y₂O₃ film's corrosion resistant properties. The laminate structure 10A may serve to enhance the anti-corrosion property and hence to provide the substrate with additional protection.

The coatings 10, 10A are trademarked as PicoArmour™, Picosun Oy, Finland.

The invention further pertains to a coated item comprising a substrate 20 coated with a plasma-resistant coating 10, 10A according to the embodiment. The coated item is advantageously configured as hardware component having the coating 10, 10A deposited over at least a portion of its surface.

The component can be configured as a three-dimensional object suitable for coating by chemical deposition methods. The inventive concept is equally applicable to producing coatings on essentially flat, planar substrates, as well on the profiled substrates that contain high aspect ratio features, such as recesses and/or perforations (generally referred to as “profiles”). Said profiled substrate can be configured as a perforated substrate, a substrate having a patterned surface or a combination of perforations with the patterned surface. The profiles can be configured discrete (e.g. in the form of discrete, individual apertures/holes) or continuous, such as grooves, channels (including through-cut channels), trenches, and the like.

The component is typically used with a plasma processing equipment and having a surface or surfaces exposed to plasma. Therefore, in some instances, the component is selected from the group consisting of: a showerhead, a diffusor for the showerhead, a pedestal, a sample holder, a valve, a valve block, a pin, a manifold, a pipe, a cylinder, a lid, and a container.

In an aspect, use of the coated item and/or of the substrate 20 coated with the plasma resistant coating 10, 10A according to the embodiments is provided in a processing chamber of a plasma assisted treatment apparatus. The apparatus can be configured as a plasma etching apparatus, an apparatus for plasma-enhanced chemical vapor deposition or an apparatus for plasma-assisted physical vapor deposition. The apparatus can be configured to generate halogen plasma (e.g. fluorine plasma, chlorine plasma), oxygen plasma, argon plasma, and the like.

In another aspect, a method for improving resistance of a substrate to plasma erosion and corrosion in plasma processing is provided. The method comprises obtaining a substrate and receiving said substrate into a reaction chamber with subsequent formation, over at least a portion of a substrate surface, of a plasma resistant yttrium-containing coating by depositing, through a process of chemical deposition in vapour phase, preferably, through Atomic Layer Deposition (ALD), a plurality of deposition layers such, that the deposition layers having a first composition alternate with the deposition layers having a second composition. In the method, the deposition layers having the first composition are mixture films (11) composed of a mixture of at least two compounds, one of said compounds being yttrium compound, preferably, yttrium oxide, whilst the deposition layers (12) having the second composition are composed of a metal fluoride.

In some configurations, the deposition layers having said first composition are mixture films 11 composed of a mixture of the first compound and the second compound, in which mixture the second compound is yttrium(III) oxide (Y₂O₃) and the first compound is a metal oxide distinct from yttrium oxide, such as any one of aluminium(III) oxide (Al₂O₃) and zirconium(IV) oxide (ZrO₂) or any non-lanthanide oxide, whilst the deposition layers 12 having said second composition are composed of the metal fluoride, in particular, yttrium (III) fluoride (YF₃).

It shall be appreciated by those skilled in the art that with the advancement of technology the basic ideas of the present invention may be implemented and combined in various ways. The invention and its embodiments are thus not limited to the examples described hereinabove, instead they may generally vary within the scope of the claims.

1. A method for producing plasma resistant coated substrates, the method comprises:
obtaining a substrate, and
depositing, over at least a portion of the substrate, a plasma resistant coating through a process of chemical deposition in vapour phase,
wherein said plasma resistant coating comprises a mixture film composed of a mixture of at least two compounds, one of said compounds being an yttrium compound.

2. The method of claim 1, wherein the mixture film is deposited in a plurality of deposition sequences, each said deposition sequence comprises depositing a first compound in at least two deposition cycles followed with depositing a second compound in a single deposition cycle, the second compound being the yttrium compound.

3. The method of claim 1, wherein the relationship between the number of deposition cycles to deposit the first compound and the number of deposition cycles to deposit the second compound in the deposition sequence is 2-10 to 1, respectively.

4. The method of claim 1, wherein the mixture film is composed of a mixture of said first compound and said second compound, in which mixture the second compound is yttrium(III) oxide (Y₂O₃) and the first compound is a metal oxide distinct from yttrium oxide.

5. The method of claim 1, wherein the mixture film is composed of a mixture of aluminium(III) oxide (Al₂O₃) and yttrium(III) oxide (Y₂O₃) to yield a solid solution of aluminium yttrium oxide (AlₓY₂₋ₓO₃).

6. The method of claim 1, further comprising:
depositing, over a deposition layer consisting of the mixture film, an additional deposition layer composed of a metal fluoride.

7. The method of claim 6, in which the steps of depositing the mixture film and the additional deposition layer composed of the metal fluoride are repeated a number (n) of times to produce a laminate coating of a desired thickness.

8. The method of claim 6, wherein a metal component in the metal fluoride, said additional deposition layer is composed of, is selected from the group consisting of: yttrium (Y), lanthanum (La), strontium (Sr), zirconium (Zr), magnesium (Mg), hafnium (Hf), terbium (Tb), and calcium (Ca).

9. A plasma resistant coating, comprising a mixture film composed of a mixture of at least two compounds, one of said compounds being an yttrium compound.

10. The coating of claim 9, wherein the mixture film is deposited in a plurality of deposition sequences, each said deposition sequence comprises depositing a first compound in at least two deposition cycles, followed with depositing a second compound in a single deposition cycle, the second compound being the yttrium compound.

11. The coating of claim 9, wherein the mixture film is composed of a mixture of said first compound and said second compound, in which mixture the second compound is yttrium(III) oxide (Y₂O₃) and the first compound is a metal oxide distinct from yttrium oxide.

12. The coating of claim 9, wherein the mixture film is composed of a mixture of aluminium(III) oxide (Al₂O₃) and yttrium(III) oxide (Y₂O₃) to yield a solid solution of aluminium yttrium oxide (AlₓY₂₋ₓO₃).

13. The coating of claim 9, wherein the content of yttrium in the mixture film is within a range of about 4 atomic percent to about 20 atomic percent.

14. The coating of claim 9, further comprising at least one additional deposition layer composed of a metal fluoride.

15. The coating of claim 9, in which a plurality of deposition layers composed of mixture films alternate with a plurality of deposition layers composed of the metal fluoride.

16. The coating claim 14, wherein a metal component in the metal fluoride, said additional deposition layer is composed of, is selected from the group consisting of: yttrium (Y), lanthanum (La), strontium (Sr), zirconium (Zr), magnesium (Mg), hafnium (Hf), terbium (Tb), and calcium (Ca).

17. The coating of claim 9, having a thickness within a range of about 10 nm to about 1000 nm.

18. A coated item, comprising a substrate coated with a plasma-resistant coating according to claim 9.

19. The coated item of claim 18 configured as a component used with a plasma processing equipment and having a surface or surfaces exposed to plasma.

20. The coated item of claim 18, configured as a component selected from the group consisting of: a showerhead, a diffusor for the showerhead, a pedestal, a sample holder, a valve, a valve block, a pin, a manifold, a pipe, a cylinder, a lid, and a container.

21. A method for performing plasma assisted treatment, comprising providing a plasma assisted treatment apparatus, providing the coated item as defined in a claim 18 in a processing chamber of the plasma assisted treatment apparatus, and performing the plasma assisted treatment.

22. A method for improving resistance of a substrate to plasma erosion and corrosion in plasma processing, the method comprises: formation, over at least a portion of a substrate surface, of an yttrium-containing plasma resistant coating by depositing, through a process of chemical deposition in vapour phase, a plurality of deposition layers such, that the deposition layers having a first composition alternate with the deposition layers having a second composition, wherein the deposition layers having the first composition are mixture films composed of a mixture of at least two compounds, one of said compounds being yttrium compound, and wherein the deposition layers having the second composition are composed of a metal fluoride.

23. The method of claim 22, wherein the deposition layers having said first composition are mixture films composed of a mixture of the first compound and the second compound, in which mixture the second compound is yttrium(III) oxide (Y₂O₃) and the first compound is a metal oxide distinct from yttrium oxide, and wherein the deposition layers having said second composition are composed of the metal fluoride.
